(19) United States
(12) Patent Application Publication
(10) Pub. No.: US 2015/0123267 A1
(43) Pub. Date: May 7, 2015

(54) PACKAGED SEMICONDUCTOR DEVICE

(71) Applicant: TAIWAN SEMICONDUCTOR MANUFACTURING COMPANY LTD., HSINCHU (TW)

(72) Inventors: MIRNG-JI LII, HSINCHU COUNTY (TW); HAO-YI TSAI, HSINCHU CITY (TW); HSIEN-WEI CHEN, HSINCHU CITY (TW); HUNG-YI KUO, TAIPEI CITY (TW)

(73) Assignee: TAIWAN SEMICONDUCTOR MANUFACTURING COMPANY LTD., HSINCHU (TW)

(21) Appl. No.: 14/073,001

(22) Filed: Nov. 6, 2013

(51) Int. Cl. H01L 23/00; H01L 21/66

(52) U.S. Cl. CPC H01L 24/14; H01L 24/11; H01L 24/08; H01L 22/32; H01L 2224/08059; H01L 2224/0801
USPC 257/737; 438/613

(57) ABSTRACT

A semiconductor device with an under-bump metallurgy (UBM) over a dielectric is provided. The UBM has a trench configured to be offset from a central point of the UBM. A distance between a center of the trench to an edge of the UBM is larger than a distance between the center of the trench to an opposite edge of the UBM. A probe pin is configured to contact the UBM and collect measurement data.

### FIELD

The present disclosure relates to a semiconductor device and method of forming the same.

### BACKGROUND

Modern integrated circuits are made up of literally millions of active devices such as transistors and capacitors. These devices are initially isolated from each other, but are later interconnected together to form functional circuits. Typical interconnect structures include lateral interconnections, such as metal lines (wirings), and vertical interconnections, such as via openings and contacts. Interconnections are increasingly determining the limits of performance and the density of modern integrated circuits. On top of the interconnect structures, bond pads are formed and exposed on the surface of the respective chip. Electrical connections are made through bond pads to connect the chip to a package substrate or another die. Bond pads can be used for wire bonding or flip-chip bonding. Flip-chip packaging utilizes bumps to establish electrical contact between a chip's input/output (I/O) pads and the substrate or lead frame of the package. Structurally, a bump actually contains the bump itself and an “under bump metallurgy” (UBM) located between the bump and an I/O pad.

In addition to receiving the bump, the UBM is used for detection of the active devices in the semiconductor device. Probes are utilized to contact the surface of the UBM so as to collect measurement data such as radio frequency, inductance and impedance. Measures to improve measurement accuracies and efficiencies are continuously being sought.

### BRIEF DESCRIPTION OF THE DRAWINGS

One or more embodiments are illustrated by way of example, and not by limitation, in the figures of the accompanying drawings, wherein elements having the same reference numeral designations represent like elements throughout. The drawings are not to scale, unless otherwise disclosed.

FIGS. 1A-1C are cross-sectional views of a semiconductor device in accordance with some embodiments of the present disclosure.

FIG. 2 is a cross-section view of a semiconductor device and a probing system in accordance with some embodiments of the present disclosure.

FIGS. 3A-3C are cross-section views of a semiconductor device in accordance with some embodiments of the present disclosure.

FIGS. 4A-4D are top views of a semiconductor device in accordance with some embodiments of the present disclosure.

FIG. 5 is a semiconductor device manufacturing method in accordance with some embodiments of the present disclosure.

FIG. 6 is a semiconductor device testing method in accordance with some embodiments of the present disclosure.

### Like reference symbols in the various drawings indicate like elements.

### DETAILED DESCRIPTION OF THE DISCLOSURE

The making and using of the embodiments of the disclosure are discussed in detail below. It should be appreciated, however, that the embodiments provide many applicable inventive concepts that can be embodied in a wide variety of specific contexts. The specific embodiments discussed are merely illustrative of specific ways to make and use the embodiments, and do not limit the scope of the disclosure. Throughout the various views and illustrative embodiments, like reference numerals are used to designate like elements. Reference will now be made in detail to exemplary embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, an apparatus in accordance with the present disclosure. It is to be understood that elements not specifically shown or described may take various forms. Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

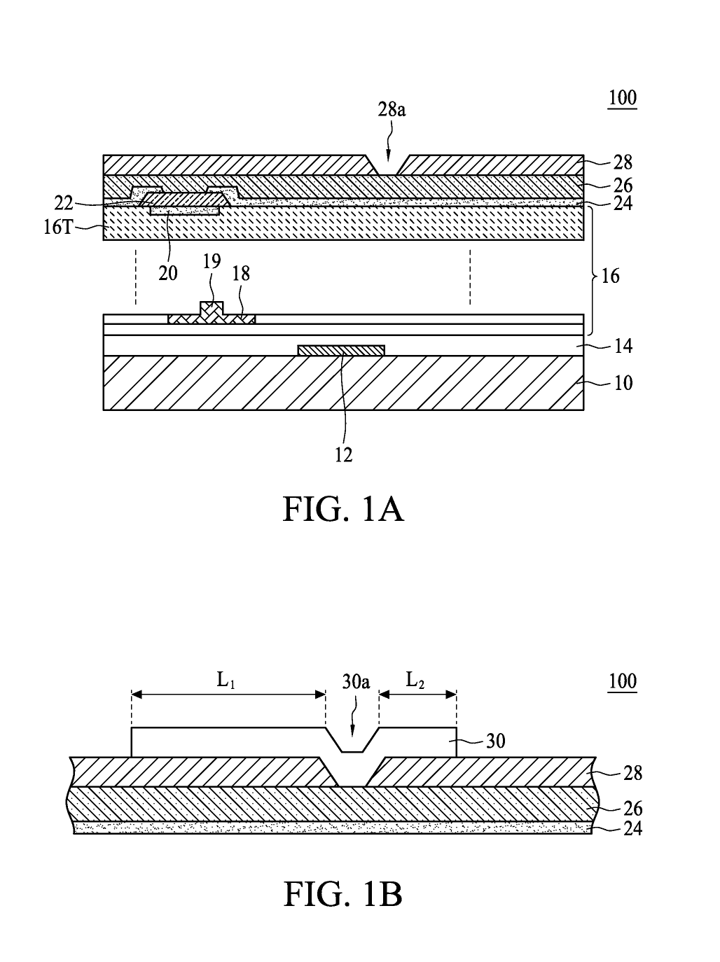

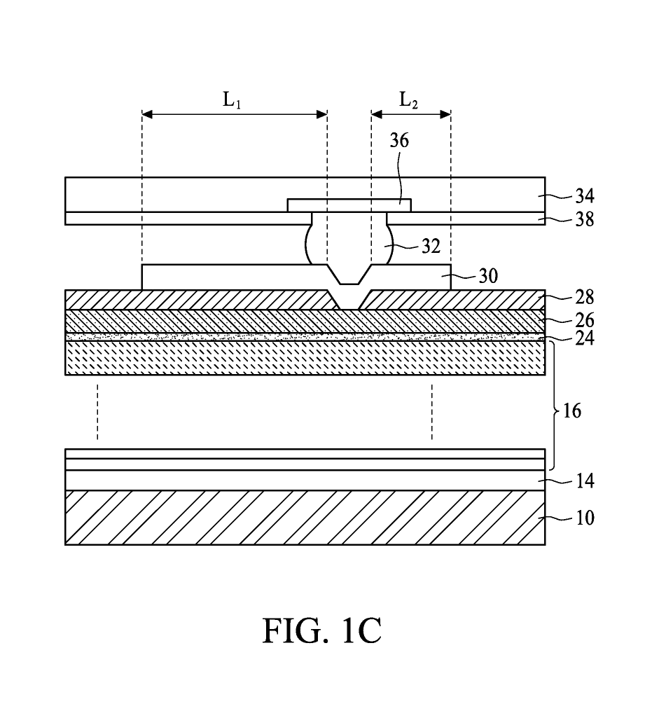

FIGS. 1A-1C are cross-sectional views of a semiconductor device in accordance with some embodiments of the present disclosure.

Referring to FIG. 1A, a portion of a substrate 10 of the semiconductor device 100 having electrical circuitry 12 formed thereon is shown. The substrate 10 may comprise, for example, bulk silicon, doped or undoped, or an active layer of a semiconductor-on-insulator (SOI) substrate. Generally, an SOI substrate comprises a layer of a semiconductor material, such as silicon, formed on an insulator layer. The insulator layer may be, for example, a buried oxide (BOX) layer or a silicon oxide layer. The insulator layer is provided on a substrate, typically a silicon substrate or a glass substrate. Other substrates, such as a multi-layered or gradient substrate may also be used.

Electrical circuitry 12 formed on the substrate 10 may be any type of circuitry suitable for a particular application. In some embodiments, the electrical circuitry 12 includes electrical devices formed on the substrate 10 with one or more dielectric layers overlying the electrical devices. Metal layers can be formed between dielectric layers to route electrical signals between the electrical devices. Electrical devices can also be formed in one or more dielectric layers. For example, the electrical circuitry 12 may include various N-type metal-oxide semiconductor (NMOS) and/or P-type metal-oxide semiconductor (PMOS) devices, such as transistors, capacitors, resistors, diodes, photo-diodes, fuses, and the like, interconnected to perform one or more functions. The functions may include memory structures, processing structures, sensors, amplifiers, power distribution, input/output circuitry, or the like. One of ordinary skill in the art will appreciate that the above examples are provided for illustrative purposes only to further explain applications of some illustrative embodiments and are not meant to limit the disclosure in any manner. Other circuitry may be used as appropriate for a given application.

Also shown in FIG. 1A is an inter-layer dielectric (ILD) layer 14. The ILD layer 14 can be formed, for example, of a low-K dielectric material, such as phosphosilicate glass (PSG), borophosphosilicate glass (BPSG), fluorinated silicate glass (FSG), SiOxCy, Spin-On-Glass, Spin-On-Polymers, silicon carbon material, compounds thereof, composites thereof, combinations thereof, or the like, by any suitable method, such as spinning, chemical vapor deposition (CVD), and/or plasma-enhanced CVD (PECVD). It should also be noted that the ILD layer 14 can comprise a plurality of dielectric layers. Contacts (not shown) can be formed through the ILD layer 14 to provide an electrical contact to the electrical circuitry 12. The contacts can be formed of, for example, one or more layers of TaN, Ta, TiN, Ti, CoW, copper, tungsten, aluminum, silver, or the like, or combinations thereof.

One or more inter-metal dielectric (IMD) layers 16 and the associated metallization layers are formed over the ILD layer 14. Generally, the one or more IMD layers 16 and the associated metallization layers (including metal lines 18, via openings 19 and metal layers 20) are used to interconnect the electrical circuitry 12 to each other and to provide an external electrical connection. The IMD layers 16 can be formed of a low-K dielectric material, such as FSG formed by PECVD techniques or high-density plasma CVD (HDPCVD), or the like, and can include intermediate etch stop layers. It should be noted that one or more etch stop layers (not shown) can be positioned between adjacent ones of the dielectric layers, e.g., the ILD layer 14 and the IMD layers 16. Generally, the etch stop layers provide a mechanism to stop an etching process when forming via openings and/or contacts. The etch stop layers are formed of a dielectric material having a different etch selectivity from adjacent layers, e.g., the underlying semiconductor substrate 10, the overlying ILD layer 14, and the overlying IMD layers 16. In some embodiments, etch stop layers can be formed of SiN, SiCN, SiCO, CN, combinations thereof, or the like, deposited by CVD or PECVD techniques.

The metallization layers including metal lines 18 and via openings 19 can be formed of copper or copper alloys, although they can also be formed of other metals. Further, the metallization layers include a top metal layer 20 formed and patterned in or on the uppermost IMD layer 16T to provide external electrical connections and to protect the underlying layers from various environmental contaminants. The uppermost IMD layer 16T can be formed of a dielectric material, such as silicon nitride, silicon oxide, undoped silicon glass, and the like.

Thereafter, a conductive pad 22 is formed to contact the top metal layer 20, or alternatively, electrically coupled to top metal layer 20 through a via. The conductive pad 22 can be formed of aluminum, aluminum copper, aluminum alloys, copper, copper alloys, or the like. One or more passivations, such as passivation 24, are formed over the conductive pads 22 and the uppermost IMD layer 16T. The passivation 24 can be formed of a dielectric material, such as undoped silicate glass (USG), silicon nitride, silicon oxide, silicon oxynitride or a non-porous material by any suitable method, such as CVD, PVD, or the like. The passivation 24 can be a single layer or a laminated layer. One of ordinary skill in the art will appreciate that a single layer of conductive pad and a passivation are shown for illustrative purposes only. As such, other embodiments can include any number of conductive layers and/or passivations. The passivation 24 is then patterned by the use of masking methods, lithography technologies, etching processes, or combinations thereof, such that an opening is formed to expose a portion of conductive pad 22. In an embodiment, the passivation 24 is patterned to cover the peripheral portion of the conductive pad 22, and to expose the central portion of conductive pad 22 through the opening.

Next, an interconnect 26 is formed over the passivation 24. In some embodiments, the interconnect 26 is patterned to electrically connect the conductive pad 22. In certain embodiments, the interconnect 26 extends to electrically connect the conductive pad 22 through an opening in the passivation 24. The interconnect 26 is a metallization layer, which may include, but not limited to, for example copper, aluminum, copper alloy, nickel or other mobile conductive materials using plating, electroless plating, sputtering, chemical vapor deposition methods, and the like. In some embodiments, the interconnect 26 further includes a nickel-containing layer (not shown) on top of a copper-containing layer. In some embodiments, the interconnect 26 also functions as power lines, re-distribution lines (RDL), inductors, capacitors or any passive components. In certain embodiments, the interconnect 26 is a post-passivation interconnect (PPI).

Thereafter, a dielectric 28 is formed on the interconnect 26. In some embodiments, the dielectric 28 is patterned to have an opening 28a exposing a portion of the interconnect 26. The dielectric 28 can be, for example, a polymer layer. The polymer layer can be formed of a polymer material such as an epoxy, polyimide, benzocyclobutene (BCB), polybenzoxazole (PBO), and the like, although other relatively soft, often organic, dielectric materials can also be used. In some embodiments, the dielectric 28 is formed of a non-organic material selected from un-doped silicate glass (USG), silicon nitride, silicon oxynitride, silicon oxide, and combinations thereof. The formation methods of the dielectric 28 include spin coating or other methods. In some embodiments, the dielectric 28 is an optional layer, which can be skipped in the semiconductor device. In subsequent cross-sectional drawings, semiconductor substrate 10, electrical circuitry 12, ILD layer 14, IMD layers 16, metallization layers 18 and 19, and top metal layer 20 are not illustrated, and the conductive pad 22 is formed as a part of the passivation 24.

Referring to FIG. 1B, an under-bump metallurgy (UBM) 30 is formed over the dielectric 28. The UBM 30 is configured to extend into the opening (28a in FIG. 1A) of the dielectric 28. Accordingly, the UBM 30 is electrically connected with the interconnect 26. The UBM 30 is formed by metal deposition, photolithography and etching methods. In some embodiments, the UBM 30 includes at least one metallization layer comprising titanium (Ti), tantalum (Ta), titanium nitride (TiN), tantalum nitride (TaN), copper (Cu), copper alloys, nickel (Ni), tin (Sn), gold (Au), or combinations thereof. In some embodiments, the UBM 30 includes at least one Ti-containing layer and at least one Cu-containing layer. In some embodiments, the UBM 30 has a trench 30a. Specifically, the trench 30a is configured to be offset from the central point of the UBM 30. In other words, a length Ll from an outer boundary of the trench 30a to a border of the UBM 30 is longer than a length L2 from an opposite outer boundary of the trench 30a to an opposite border of the UBM 30.

Referring to FIG. 1C, a bump 32 is provided on the UBM 30, and a substrate 34 is provided over the bump 32. In some embodiments, the bump 32 is placed on the UBM 30. In certain embodiments, the bump 32 is formed by a solder plating process with photolithography technology. A reflow process is provided so as to generate a bonding between the bump 32 and the UBM 30, and the bump 32 and the substrate 34. With reference to FIG. 1B, in some embodiments in accordance with the present disclosure, the length L1 is longer than the length L2. In other words, the bump 32 is disposed on the UBM 30 at a position offset from a central point of the UBM 30.

Referring to FIG. 1C, the substrate 34 includes a package substrate, a board, (e.g., a printed circuit board (PCB)), a wafer, a die, an interposer substrate, or other suitable substrate. In some embodiments in accordance with the present disclosure, a conductive region 36 is formed and patterned on the substrate 34, and configured to be bound with the bump 32. The conductive region 36 is a contact pad or a portion of a conductive trace, which is presented by a mask layer 38. In certain embodiments, the mask layer 38 is a solder resist layer formed and patterned on the substrate 34 to expose the conductive region 36.

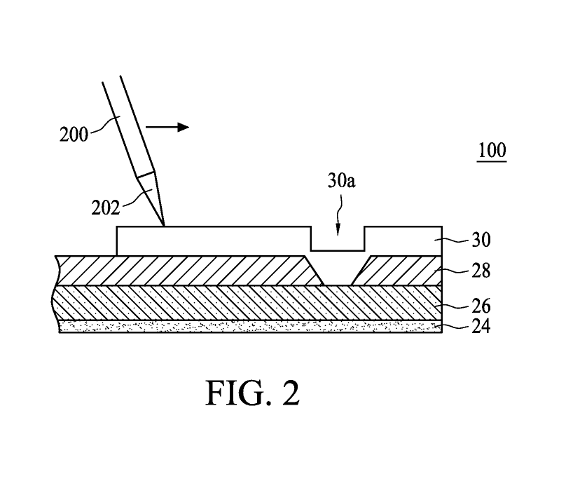

FIG. 2 is a cross-section view of a semiconductor device and a probing system in accordance with some embodiments of the present disclosure.

Referring to FIG. 2, a portion of the semiconductor device 100 is provided. A probing system 200 is applied to contact the surface of the UBM 30. Through such contact, the probing system 200 collects measurement data such as radio frequency, inductance and impedance of the structure/material of the semiconductor device 100. For example, the probing system 200 can be configured to measure the radio frequency of the interconnect 26.

In some embodiments, the probing system 200 includes a test head, a probe card having a plurality of probe pins, and a chuck. The test head is arranged to generate or route test signals for the probe pins via the probe card. The probe pins are arranged in an array and are of any configuration suitable for probing semiconductor devices. The chuck is arranged for supporting thereon a semiconductor device, and moves the supported semiconductor device toward and away from the probe pins for causing intended electrical contact between the probe pins and the conductors of the semiconductor device.

In some embodiments, the conductors include, but are not limited to, conductive traces (patterns), bonding pads, test pads, etc. Conductive traces are for routing electrical signals, power or ground voltages among components and/or integrated circuits included in/on the semiconductor device. Bonding pads are for electrical and/or mechanical connections to external devices. Test pads are arranged specifically for testing purposes. Any conductor on the surface of the semiconductor device can be considered as a conductive pad to be brought into contact with one of the probe pins for receiving test signals to probe the semiconductor device. However, not all conductors on the surface of the semiconductor device are necessarily used for probing the semiconductor device in every test.

During a semiconductor device testing or probing process, the semiconductor device is supported on the chuck. The chuck moves the semiconductor device toward the probe pins to cause mechanical and electrical contact between the probe pins and the conductors to be tested. Test signals are transmitted from the test head, to the probe pins and then to the conductors to be tested for probing the semiconductor device. In some embodiments, automated test equipment (ATE) is used to generate test signals to be sent to the probing system 200 via the test head.

In some embodiments, the test signals are high frequency test signals, for example, in the range from several megahertz (MHz) to 6 gigahertz (GHz), or even higher, e.g., up to 30 GHz. The high frequency test signals, also referred to herein as radio frequency (RF) test signals, are used to test certain RF response characteristics of one or more components and/or integrated circuits included in/on the semiconductor device, which are configured to operate in RF environments.

Referring to FIG. 2, in some embodiments in accordance to the present disclosure, the probing system 200 is configured to contact the UBM 30 with a probing pin 202. A thickness of the UBM and the dielectric is larger than 7 μm. A depth of the trench 30a is larger than 4 μm. A diameter of the probing pin 202 is between about 5 μtm and about 15 μm. A dimension (diameter or length) of the trench 30a is between about 10 μm and 30 m. In some embodiments, a semiconductor device 100 with a prolonged UBM 30 overlying the dielectric 28 is provided. In other words, a semiconductor device 100 with an UBM 30 having a trench 30a offset from a central point of the UBM 30 is provided. The prolonged UBM 30 reduces the possibility that the probe pin 202 be dropped into the trench 30a when the probing system 200 collects measurement data.

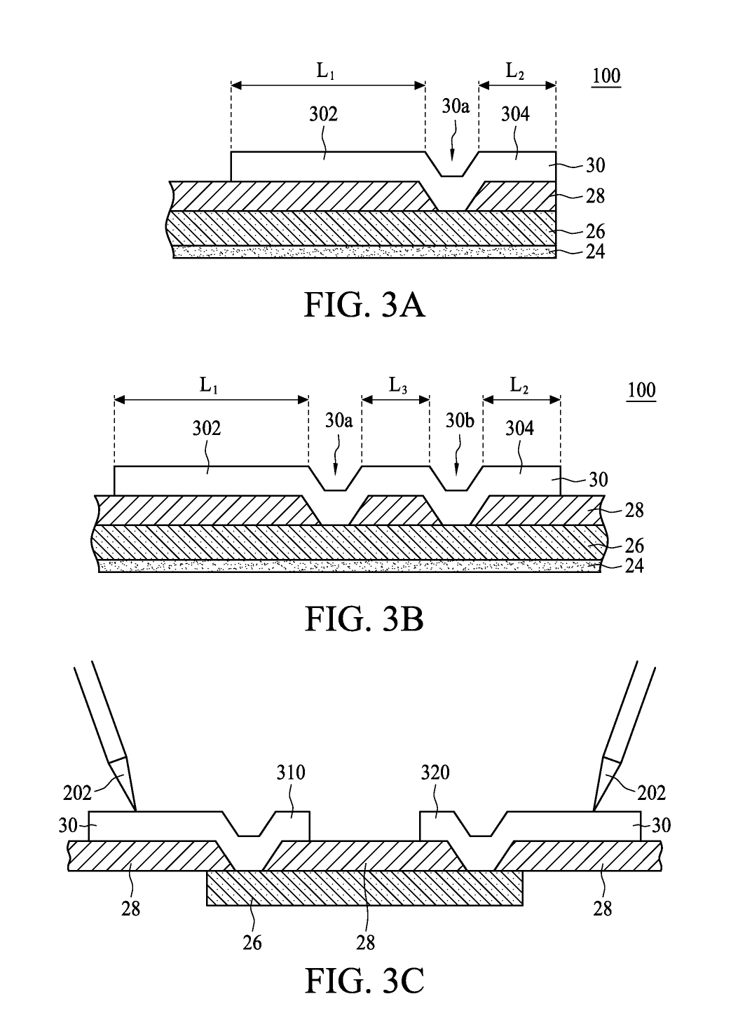

FIGS. 3A-3C are cross-section views of a semiconductor device in accordance with some embodiments of the present disclosure.

Referring to FIG. 3A, the UBM 30 overlies the dielectric 28 and has a trench set. In some embodiments in accordance to the present disclosure, the trench set has a trench 30a. The UBM 30 further has a first skirt 302 at one side of the trench 30a and a second skirt 304 at an opposite side of the trench 30a. The first skirt 302 is larger in dimension than the second skirt 304. For example, the first skirt 302 has a length L1 measured from an outer boundary of the trench 30a to a border of the UBM 30, and the second skirt 304 has a length L2 measured from an opposite outer boundary of the trench 30a to an opposite border of the UBM 30. The length L1 of the first skirt 302 is longer than the length L2 of the second skirt 304. In certain embodiments, when a probe pin is configured to contact the UBM 30, the probe pin can be dropped at the first skirt 302, instead of the second skirt 304. The prolonged UBM 30, i.e., the first skirt 302, provides a substantially larger contacting surface of the UBM 30, comparing to the second skirt 304, for the probe pin. Consequently, the possibility of the probe pin been dropped into the trench 30a is reduced.

In some embodiments, the length L1 is between about 50 μm and about 200 μm. The length L2 is between about 10 μm and about 50 μm. The difference between the length L1 and the length L2 is between about 50 μm and about 100 μm. In certain embodiments, the length L1 is between about 70 μm and about 100 μm. The length L2 is between about 15 μm and about 30 μm. The difference between the length L1 and the length L2 is between about 60 μm and about 80 μm. The larger the difference between the length L1 and the length L2, the lower the possibility that the probe pin been dropped into the trench 30a is.

Referring to FIG. 3B, in some embodiments, the trench set has a first trench 30a and a second trench 30b. The UBM 30 has a first skirt 302 at one side of the trench set and a second skirt 304 at an opposite side of the trench set. The first skirt 302 has a length L1 measured from an outer boundary of the trench set to a border of the UBM 30, and the second skirt 304 has a length L2 measured from an opposite outer boundary of the trench set to an opposite border of the UBM 30. In other words, the first skirt has a length L1 measured from an outer boundary of the first trench 30a, and the second skirt 304 has a length L2 measured from an opposite outer boundary of the second trench 30b to an opposite border of the UBM 30. The distance between the first trench 30a and the second trench 30b is represented by the length L3. The length L3 is between about 30 μm and about 45 μm. The length L1 of the first skirt 302 is longer than the length L2 of the second skirt 304. In certain embodiments, when a probe pin is configured to contact the UBM 30, the probe pin can be dropped at the first skirt 302, instead of the second skirt 304. The prolonged UBM 30, i.e., the first skirt 302, provides a substantially larger contacting surface of the UBM 30, comparing to the second skirt 304, for the probe pin. Consequently, the possibility of the probe pin been dropped into the trench 30a is reduced. Detailed technical features of the first skirt 302, the second skirt 304, and the differences thereof have been disclosed in the previous disclosures and therefore will not be repeated.

In certain embodiments in accordance to the present disclosure, the trench set of the UBM has multiple trenches. Such multiple trenches are offset from a central point of the UBM so as to provide a substantially larger contacting surface of the UBM at one side of the trench set than the other for the probe pin. The multiple trenches also serve to reduce the depreciation of the testing signal from the probe pin. Multiple trenches provide multiple signal accessing points, and accordingly reduce the impedance of the components in or on the semiconductor device tested.

Referring to FIG. 3C, in some embodiments, a semiconductor device with two UBMs 310, 320 are provided. The first UBM 310 is configured to extend into an opening of the dielectric 28 and electrically connect the dielectric 26. The second UBM 320 is configured to extend into another opening of the dielectric 28 and electrically connect the dielectric 26. In other words, the first UBM 310 is electrically connected to the second UBM 320 through the dielectric 26. When probe pins 202 are applied to contact the first UBM 310 and the second UBM 320 respectively, a test signal can be communicated between the probe pins 202. Accordingly, the radio frequency, inductance and impedance of the structure/material of the semiconductor device can be detected. For example, a measurement data of the impedance of the interconnect 26 is first collected. Thereafter, a difference in the impedance of the interconnect 26 may indicate that the length of the interconnect 26 has been changed. In addition, based on the measurement data initially collected, characteristics of the other structure/material of the semiconductor device can be measured and estimated. For example, a change in the impedance of the interconnect 26 indicates that the width of the UBM 30 and/or the thickness of the dielectric 28 has been changed. Accordingly, the semiconductor device with two UBMs 310, 320 is configured to allow the monitoring the characteristics of the structure/material of the semiconductor device.

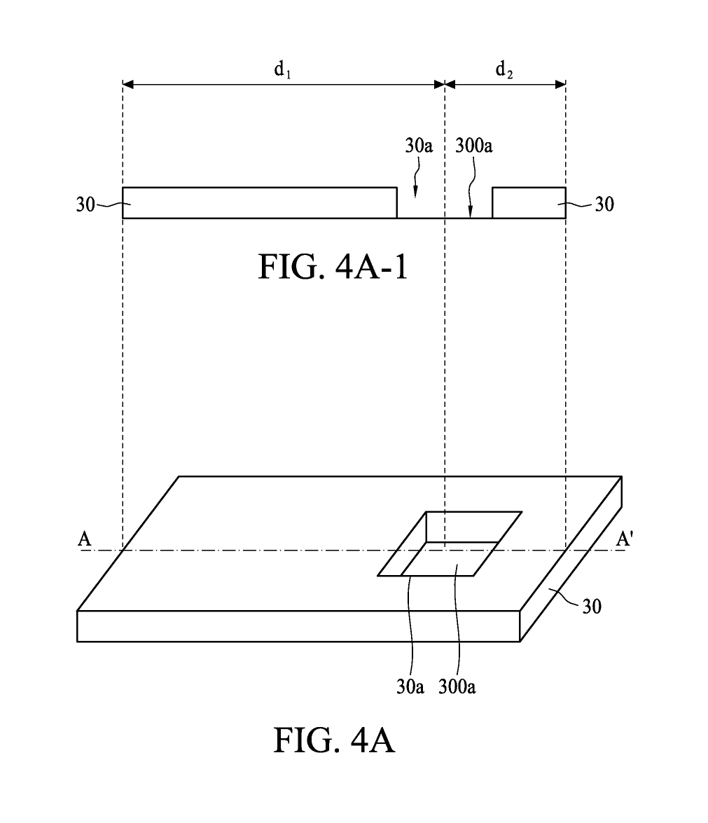

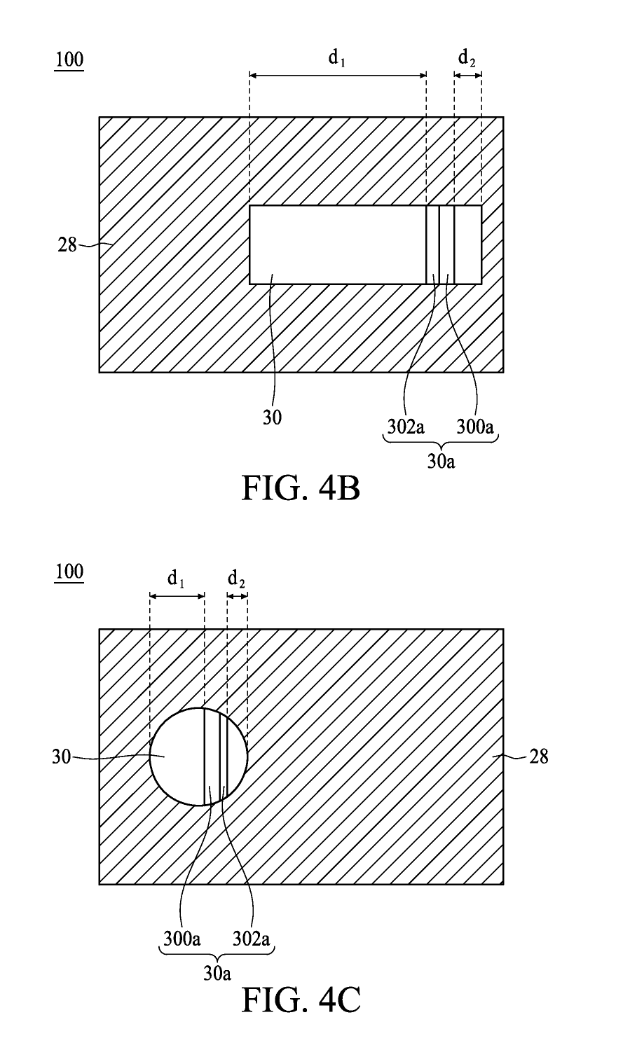

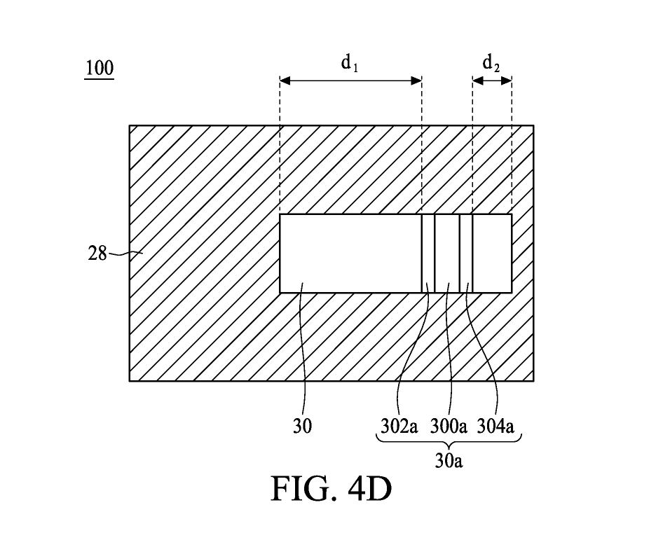

FIGS. 4A-4D are different views of a semiconductor device in accordance with some embodiments of the present disclosure.

FIG. 4A is a perspective view of an UBM 30 of the semiconductor device (not depicted) in accordance with some embodiments of the present disclosure. (The semiconductor device 100 including the dielectric 28 underlying the UBM 30 is omitted for clarity). FIG. 4A-1 is a cross-section view of the UBM 30 along the dotted line A-A′. Reference can be made to FIG. 2 for a more detailed cross-section view of the UBM 30 and the underlying semiconductor device 100. The UBM 30 has a trench 30a. In some embodiments, the UBM 30 is substantially quadrilateral. In certain embodiments, the UBM 30 is round, triangular or any shape that a person having ordinary skill in the art would deem fit.

In some embodiments, the trench 30a is configured to be offset from a central point of the UBM 30. In other words, the trench 30a is not at the central point of the UBM 30. The trench 30a has a base portion 300a. In some embodiments, the base portion 300a is substantially quadrilateral. In certain embodiments, the trench 30a is round, triangular or any shape that a person having ordinary skill in the art would deem fit. It is to be noted that the shapes of the UBM 30 and the base portion 300a may not be identical. Different combinations of UBM and its base portion shapes are within the contemplated scope of the present disclosure.

Referring to FIG. 4A-1, a first distance dl is measured from the center of the trench 30a to an edge of the UBM 30, and a second distance d2 is measured from the center of the trench 30a to an opposite edge of the UBM 30. The first distance d1 is larger than the second distance d2. In other words, the UBM 30 has a larger contacting surface at one side of the trench 30a than that of the opposite side of the trench 30a. In some embodiments, the difference between the first distance d1 and the second distance d2 is between about 50 μm and about 100 μm. In certain embodiments, the difference between the distance d1 and the distance d2 is between about 60 μm and about 80 μm. Accordingly, a probe pin can be applied to the larger contacting surface of the UBM 30. A distance can be kept between the probe pin and the trench 30a. Therefore, the possibility of the probe pin been dropped into the trench 30a is reduced.

Referring to FIG. 4B, the trench 30a has a base portion 300a and a perimeter portion 302a next to the base portion 300a. The based portion 300a is substantially flat. The perimeter portion 302a is an angled wall, configured to rise from the base portion 300a to the UBM 30. Accordingly, the trench 30a is in a partially tapered shape.

In some embodiments in accordance to the present disclosure, the trench 30a is configured to be offset from the central point of the UBM 30. In other words, a distance d1 from an outer boundary of the perimeter portion 302a to an edge of the UBM 30 is different from a distance d2 from an outer boundary of the base portion 300a to an opposite edge of the UBM 30. Here, the distance d1 is larger than the distance d2. The difference between the distance d1 and the distance d2 is between about 50 μm and about 100 μm. In certain embodiments, difference between the distance d1 and the distance d2 is between about 60 μm and about 80 μm. In some embodiments, the distance d1 is smaller than the distance d2.

Referring to FIG. 4C, a semiconductor device with a round UBM 30 is provided. The UBM 30 has a trench 30a having a base portion 300a and a perimeter portion 302a. FIG. 4C depicts an exemplary embodiment having different shapes of trench 30a and the base potion 300a. In addition, the distance d1 from an outer boundary of the perimeter portion 302a to an edge of the UBM 30 is different from the distance d2 from an outer boundary of the base portion 300a to an opposite edge of the UBM. Here, the distance dl is smaller than the distance d2.

Referring to FIG. 4D, an UBM 30 having a trench 30a is provided. The trench 30a has a base portion 300a and a first perimeter portion 302a and a second perimeter portion 304a opposite to the first perimeter portion 302. The base portion 300a is substantially flat. The first perimeter portion 302a and the second perimeter portion 304a are angled walls, configured to rise from the base portion 300a to the UBM 30. Accordingly, the trench 30a is in a tapered shape.

In some embodiments in accordance to the present disclosure, the trench 30a is configured to be offset from the central point of the UBM 30. A distance d1 is measured from an outer boundary of the first perimeter portion 302a to a first edge of the UBM 30.

A second distance d2 is measured from an outer boundary of the second perimeter portion 304 to a second edge of the UBM 30. The first edge of the UBM 30 is parallel to the outer boundary of the first perimeter portion 302a. The second edge of the UBM 30 is parallel to the outer boundary of the second perimeter portion 304a. The first edge and the second edge of the UBM 30 are on opposite ends of the UBM 30. The first distance d1 is larger than the second distance d2. In other words, the UBM 30 is prolonged so as to create a substantially larger contacting surface of the UBM 30 for the probe pin. Consequently, the possibility of the probe pin been dropped into the trench 30a is reduced.

In some embodiments, the distance d1 is between about 50 μm and about 200 μm. The distance d2 is between about 10 μm and about 50 μm. The difference between the distance d1 and the distance d2 is between about 50 μm and about 100 μm. In certain embodiments, the distance d1 is between about 70 μm and about 100 μm. The distance d2 is between about 15 μm and about 30 μm. The difference between the distance d1 and the distance d2 is between about 60 μm and about 80 μm. The larger the difference between the distance d1 and the distance d2, the lower the possibility that the probe pin been dropped into the trench 30a is.

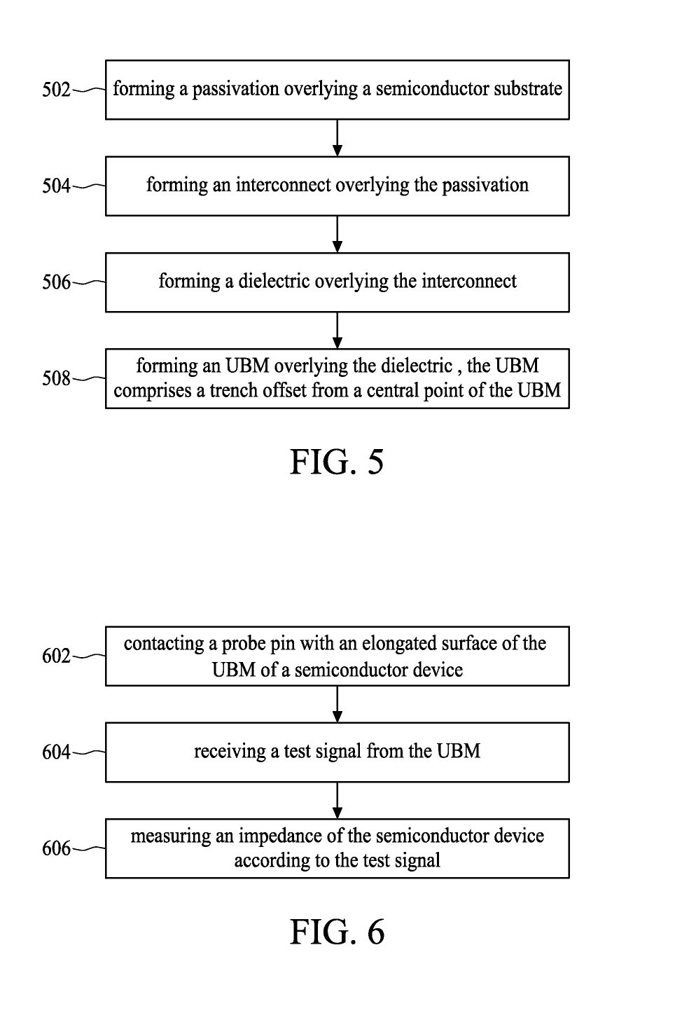

FIG. 5 is a semiconductor device manufacturing method in accordance with some embodiments of the present disclosure.

Referring to FIG. 5, in operation 502, a passivation is formed over a semiconductor substrate. In operation 504, an interconnect is formed over the passivation. In operation 506, a dielectric is formed over the interconnect. In operation 508, an under-bump metallurgy (UBM) is formed over the dielectric. The UBM has a trench configured to be offset from a central point of the UBM. Accordingly, on one side of the trench of the UBM, a substantially larger contacting surface of the UBM is provided for a probe pin to conduct measurement data collection.

FIG. 6 is a semiconductor device testing method in accordance with some embodiments of the present disclosure.

Referring to FIG. 6, in operation 602, a probe pin is configured to contact an elongated surface of an under-bump metallurgy (UBM) of a semiconductor device. The UBM has a trench, and the elongated surface extends from the trench. The elongated surface is longer than the surface of the UBM on the opposite side of the trench. In operation 604, the probe receives a test signal from the UBM. In operation 606, the impedance of the semiconductor device is measured according to the test signal.

According to the impedance measured, characteristics of the other structure/material of the same or a different semiconductor device can be measured and estimated according to the test signal.

In some embodiments, a semiconductor device having an under-bump metallurgy (UBM) overlying a dielectric is provided. The UBM has a trench offset from a central point of the UBM. In other words, the UBM is prolonged and divided by the trench. Accordingly, one end of the UBM (at one side of the trench) is larger in dimension than the other end of the UBM (at an opposite of the trench). Therefore, a substantially larger contacting surface of the UBM is provided for probe pin so as to conduct measurement data collection. In addition, the chance of a probe pin been dropped into the trench is lowered.

In some embodiments, a semiconductor device has a passivation overlying a semiconductor substrate. An interconnect is configured to overly the passivation. A dielectric is configured to overly the interconnect. The interconnect has openings. A portion of the interconnect is accessible through the openings. An under-bump metallurgy (UBM) is configured to overly the dielectric. The UBM is configured to extend into the openings so as to create electrical connection with the interconnect. The UBM has a trench set offset from a central point of the UBM. In certain embodiments, the trench set has a first trench and a second trench.

In some embodiments, a method for manufacturing semiconductor device is provided. The method includes: forming a passivation overlying a semiconductor substrate; forming an interconnect overlying the passivation; forming a dielectric overlying the interconnect; and forming an UBM overlying the dielectric. The UBM has a trench offset from a central point of the UBM.

Although the present invention and its advantages have been described in detail, it should be understood that various changes, substitutions and alterations can be made herein without departing from the spirit and scope of the invention as defined by the appended claims. For example, many of the processes discussed above cancan be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor device, comprising:
an under-bump metallurgy (UBM) overlying a dielectric, the UBM having a trench,
wherein the trench is offset from a central point of the UBM,
wherein the trench has a base portion at a center of the trench,
wherein the UBM has a first skirt and a second skirt, the first skirt being greater in dimension than the second skirt, and a terminal portion of the first skirt not being contacting with a conductive material.

2. The semiconductor device according to claim 1, wherein the base portion is substantially quadrilateral.

3. The semiconductor device according to claim 1, wherein the UBM is substantially quadrilateral.

4. The semiconductor device according to claim 1, wherein a first distance from the center of the trench to an edge of the UBM is larger than a second distance between the center of the trench to an opposite edge of the UBM.

5. The semiconductor device according to claim 4, wherein a difference between the first distance and the second distance is about 50 μm and about 100 μm.

6. The semiconductor device according to claim 1, wherein the trench has a perimeter portion next to the base portion,
wherein a distance from an outer boundary of the perimeter portion to an edge of the UBM is different from a distance from an outer boundary of the base portion to an opposite edge of the UBM.

7. The semiconductor device according to claim 1, wherein the trench has a first perimeter portion and a second perimeter portion, and the first perimeter portion and the second perimeter portion are at opposites sides of the base portion,
wherein the UBM has a first distance from an outer boundary of the first perimeter portion to a first edge of the UBM, and a second distance from an outer boundary of the second perimeter portion to a second edge of the UBM,
wherein the first edge is parallel to the outer boundary of the first perimeter portion, and the second edge is parallel to the outer boundary of the second perimeter portion,
wherein the first edge is opposite to the second edge,
wherein the first distance is larger than the second distance.

8. The semiconductor device according to claim 7, wherein the first distance is between about 50 μm and about 150 μm.

9. The semiconductor device according to claim 7, wherein the second distance is between about 10 μm and about 50 μm.

10. The semiconductor device according to claim 7, wherein a difference between the first distance and the second distance is about 50 μm and about 100 μm.

11-20. (canceled)

21. The semiconductor device of claim 1, further comprising:
a passivation overlying a first substrate;
an interconnect overlying the passivation;
wherein the dielectric overlying the interconnect, the dielectric comprising an opening configured for exposing a portion of the interconnect; and
wherein the under-bump metallurgy (UBM) overlying the dielectric, the UBM extending into the opening and electrically connecting with the interconnect, the UBM having a first trench and a second trench;
a bump disposed in one of the first trench and the second trench; and
a second substrate over the bump, wherein the second substrate is electrically connected to the UBM through the bump.

22. The semiconductor device according to claim 21,
wherein the first skirt and the second skirt are on opposite sides of the first trench and the second trench.

23. The semiconductor device according to claim 22, wherein a length of the first skirt is longer than a length of the second skirt,
wherein the length of the first skirt is measured from an outer boundary of the trench set to a border of the UBM, and the length of the second skirt is measured from an opposite outer boundary of the trench set to an opposite border of the UBM.

24. The semiconductor device according to claim 23, wherein the length of the first skirt is between about 50 μm and about 200 μm.

25. The semiconductor device according to claim 23, wherein the length of the second skirt is between about 10 μm and about 50 μm.

26. The semiconductor device according to claim 23, wherein a difference between the length of the first skirt and the second skirt is between about 50 μm and about 100 μm.

27. The semiconductor device according to claim 21, wherein a length between the first trench and the second trench is between about 30 μm and about 45 μm.

28. The semiconductor device according to claim 21, wherein a thickness of the UBM and the dielectric is greater than about 7 μm.

29. The semiconductor device according to claim 21, wherein a depth of the first trench or the second trench is greater than about 4 μm.

30. The semiconductor device according to claim 1, wherein the UBM having a first trench and a second trench, the first trench and the second trench being offset from the central portion of the UBM.
